(19) United States
(12) Patent Application Publication
(10) Pub. No.: US 2017/0173718 A1
(43) Pub. Date: Jun. 22, 2017

(54) METAL PATCH, METHOD FOR MANUFACTURING THE SAME AND BONDING METHOD BY USING THE SAME

(71) Applicant: Industrial Technology Research Institute, Hsinchu (TW)

(72) Inventors: Yi-Hao Huang, Taoyuan City (TW); Min-Chieh Chou, Taipei City (TW); Wen-Hua Zhang, Hsinchu County (TW); Meng-Chi Huang, Taoyuan City (TW)

(21) Appl. No.: 14/977,639

(22) Filed: Dec. 22, 2015

(30) Foreign Application Priority Data
Dec. 16, 2015 (TW) 104142373

(51) Int. Cl. B23K 1/00; C25D 3/46; H01L 23/00; C25D 5/10; C23C 28/00; C25D 3/48; C25D 3/56

(52) U.S. Cl. CPC B23K 1/0016; C25D 3/48; C25D 3/46; C25D 3/56; C25D 5/10; C23C 28/321; H01L 24/83; H01L 24/29; H01L 2224/8382; H01L 2924/20105; H01L 2924/01029; H01L 2924/01028; H01L 2924/01047; H01L 2924/01079; H01L 2924/0105

(57) ABSTRACT

A metal patch suitable for connecting a high-power element and a substrate is provided. The metal patch includes an intermediate metal layer, two first metal layers, and two second metal layers. The first metal layers are respectively disposed on two opposite surfaces of the intermediate metal layer. The intermediate metal layer is located between the first metal layers. The melting point of each of the first metal layers is greater than 800° C. The second metal layers are respectively disposed on the first metal layers. The intermediate metal layer and the first metal layers are located between the second metal layers. The material of each of the second metal layers includes an indium-tin alloy. Each of the first metal layers and the corresponding second metal layer can generate an intermetal via a solid-liquid diffusion reaction.

### CROSS-REFERENCE TO RELATED APPLICATION

This application claims the priority benefit of Taiwan application serial no. 104142373, filed on Dec. 16, 2015. The entirety of the above-mentioned patent application is hereby incorporated by reference herein and made a part of this specification.

### TECHNICAL FIELD

The invention relates to a connecting element for packaging, and more particularly, to a metal patch for connecting a high-power element and a substrate and a manufacturing method thereof, and a bonding method for connecting the high-power element and the substrate using the metal patch.

### BACKGROUND

A high-power element (an element such as MOSFET, IGBT, and LED) has the characteristics of large area and high heat flux density. Therefore, the high-power element is generally disposed on a heat dissipation substrate to reduce the temperature of the high-power element, so as to ensure the high-power element can operate normally. Common materials currently used to bond the high-power element to the substrate include silver paste and lead-free solder. The silver paste is formed by mixing silver metal particles and a polymer material. However, the polymer material is readily degraded due to temperature change in the external environment, and therefore the reliability of the silver paste is reduced. Moreover, the lead-free solder can tolerate temperatures of about 150° C. or less, and therefore when the temperature of the high-power element is higher than 175, a severe creep effect occurs to the lead-free solder, such that the reliability of the lead-free solder is reduced.

### SUMMARY

The invention provides a metal patch suitable for connecting a high-power element and a substrate.

A metal patch of the invention includes an intermediate metal layer, two first metal layers, and two second metal layers. The first metal layers are respectively disposed on two opposite surfaces of the intermediate metal layer. The intermediate metal layer is located between the first metal layers. The melting point of each of the first metal layers is greater than 800° C. The second metal layers are respectively disposed on the first metal layers. The intermediate metal layer and the first metal layers are located between the second metal layers. The material of each of the second metal layers includes an indium-tin alloy. Each of the first metal layers and the corresponding second metal layer can generate an intermetal via a solid-liquid diffusion reaction.

Based on the above, in the invention, the metal patch can be made beforehand and then connected to the high-power element and the substrate, and therefore a bonding layer (such as a solder layer or a metal layer) does not need to be formed on the high-power element and the substrate beforehand. Moreover, the material of the second metal layers of the metal patch adopts an indium-tin alloy, and therefore the metal patch can be bonded at a lower temperature. After the bonding is complete, the bonding interface (i.e., intermetal layer) between the metal patch and the high-power element has higher temperature tolerance, and the bonding interface (i.e., intermetal layer) between the metal patch and the substrate also has higher temperature tolerance. Therefore, for the bonding of the high-power element and the substrate, the metal patch has the characteristics of “low-temperature bonding” and “high-temperature usage”.

Several exemplary embodiments accompanied with figures are described in detail below to further describe the invention in details.

### BRIEF DESCRIPTION OF THE DRAWINGS

FIG. 1A to FIG. 1C are respectively cross-sectional schematics of a metal patch connecting a high-power element and a substrate before, during, and after bonding according to an embodiment of the invention.

FIG. 2A to FIG. 2C are respectively cross-sectional schematics of a metal patch connecting a high-power element and a substrate before, during, and after bonding according to another embodiment of the invention.

FIG. 3A to FIG. 3C are respectively cross-sectional schematics of a metal patch connecting a high-power element and a substrate before, during, and after bonding according to an embodiment of the invention.

FIG. 4A to FIG. 4C are respectively cross-sectional schematics of a metal patch connecting a high-power element and a substrate before, during, and after bonding according to another embodiment of the invention.

FIG. 5 shows the relationship of the bond strength between a metal patch and a high-power element against time and thrust.

FIG. 6 shows the relationship of the bond strength between a metal patch and a substrate against time and thrust.

### DETAILED DESCRIPTION OF DISCLOSED EMBODIMENTS

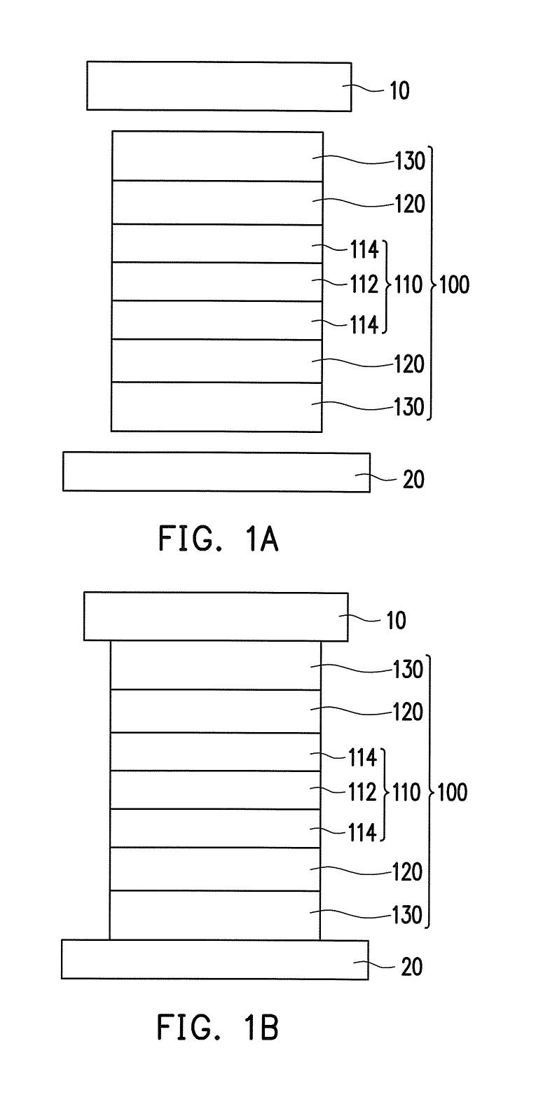

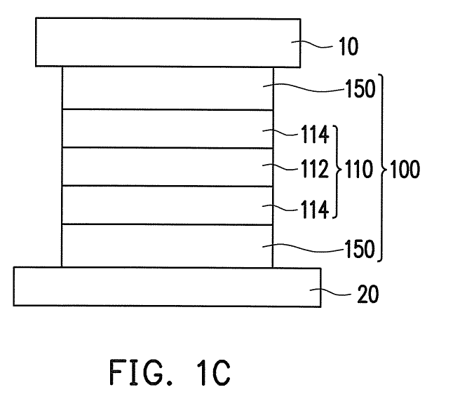

Referring to FIG. 1A, in the present embodiment, a metal patch 100 is suitable for connecting a high-power element 10 and a substrate 20. The high-power element 10 is, for instance, an element such as a metal-oxide-semiconductor field-effect transistor (MOSFET), an insulated gate bipolar transistor (IGBT), and a light-emitting diode (LED), but the invention is not limited thereto. The substrate 20 can have a cooling function, such as a copper substrate, but the invention is not limited thereto. The metal patch 100 includes an intermediate metal layer 110. The intermediate metal layer 110 is a multilayered structure. The intermediate metal layer 110 includes a base layer 112 and two barrier layers 114. The barrier layers 114 are respectively disposed on two opposite surfaces of the base layer 112, such that the base layer 112 is located between the barrier layers 114. In the present embodiment, the material of the base layer 112 includes copper, and the thickness can be 10 micrometers to 50 micrometers, but are not limited thereto. The material of each of the barrier layers 114 includes nickel, a nickel-phosphorus alloy, titanium, or chromium. The barrier layers 114 are used as a shield in the solid-liquid diffusion reaction in the manufacture, and can also be used as adhesive layers, as described in detail later.

The metal patch 100 further includes two first metal layers 120. The first metal layers 120 are respectively disposed on two opposite surfaces of the intermediate metal layer 110, such that the intermediate metal layer 110 is located between the first metal layers 120. Specifically, the first metal layers 120 are respectively disposed on the corresponding barrier layer 114, and are respectively connected to the surface of the barrier layers 114 opposite to the base layer 112. In particular, the barrier layers 114 can be used as adhesive layers at the same time, and bonding between the base layer 112 and the first metal layers 130 can be improved via the barrier layers 114. The melting point of each of the first metal layers 120 is greater than 800° C. In the present embodiment, the material of each of the first metal layers 120 includes silver or gold. Moreover, a metal of the same material can be selected for the two first metal layers 120 and be disposed on two opposite surfaces of the intermediate metal layer 110. In another embodiment, the two first metal layers 120 can also adopt metals of different materials.

The metal patch 100 further includes two second metal layers 130. The second metal layers 130 are respectively disposed on the first metal layers 120, such that the intermediate metal layer 110 and the first metal layers 120 are located between the second metal layers 130. Specifically, the metal patch 100 is a sandwich structure including, in the order of outside to inside, the second metal layers 130, the first metal layers 120, and the intermediate metal layer 110. The material of each of the second metal layers 130 includes an indium-tin alloy. Each of the first metal layers 120 and the corresponding second metal layer 130 generate an intermetal via solid-liquid diffusion. In the present embodiment, each of the second metal layers 130 contains 5% to 55% of tin, such that the range of melting point of each of the second metal layers 130 is 118° C. to 150° C. In an embodiment, the indium-tin percentage of each of the second metal layers 130 is 52:48, and the melting point thereof can be substantially about 125° C. Since the second metal layers 130 have a lower melting point, during the bonding procedure, a lower bonding temperature can be used, such as lower than 200° C.

Referring to FIG. 1A and FIG. 1B, the metal patch 100 is positioned between the high-power element 10 and the substrate 20, such that the metal patch 100 connects the high-power element 10 and the substrate 20. Then, referring to FIG. 1B and FIG. 1C, each of the first metal layers 120 and the corresponding second metal layer 130 in contact therewith are reacted in solid-liquid diffusion at a lower bonding temperature such as 150° C. or 180° C. and an intermetal having a high melting point is generated. The high melting point here is, for instance, 400° C. or more. Specifically, the metal patch 100 is first preliminarily bonded respectively at the contact surface with the high-power element 10 and the substrate 20, mainly to preliminarily fix the positions of the metal patch 100, the high-power element 10, and the substrate 20. The preliminary bonding temperature only needs to be greater than the melting point of each of the second metal layers 130, such as 150° C. or 180° C., the reaction time of the preliminary bonding is less than 10 seconds, and an intermetal thin film is respectively generated at the contact surface of the metal patch 100 with the high-power element 10 and the substrate 20 at this point, such that the high-power element 10 and the substrate 20 are preliminarily bonded and fixed via the metal patch 100. Then, the preliminarily bonded metal patch 100, high-power element 10, and substrate 20 are placed in an oven to perform a solid-liquid diffusion reaction. The bonding temperature at this point is also greater than the melting point of each of the second metal layers 130, such as 150° C. or 180° C., and the reaction time of the solid-liquid diffusion is greater than or equal to 0.5 hours, but are not limited thereto. Mainly, the material of each of the first metal layers 120 and the corresponding second metal layer 130 in contact therewith are to be reacted in the solid-liquid diffusion into a high-melting point intermetal until each of the second metal layers 130 is completely consumed.

More specifically, since the bonding process adopts a low bonding temperature, only the second metal layers 130 generate a melting reaction, and the first metal layers 120 in contact with the second metal layers 130 generate a solid-liquid diffusion reaction with the second metal layers 130 in molten state, so as to generate an intermetal having a high melting point at the contact surfaces of the metal patch 100 with the high-power element 10 and the substrate 20, such as an alloy rich in silver-indium, silver-tin, gold-indium, or gold-tin. It should be mentioned that, the composition of the intermetal is mainly decided according to the material selected for the first metal layers 120 and the second metal layers 130. Moreover, the reaction time of the bonding process and the thickness of the first metal layers 120 and the second metal layers 130 also affect the composition of the intermetal. Referring to FIG. 1C, each of the first metal layers 120 and the corresponding second metal layer 130 are completely consumed in the solid-liquid diffusion reaction of the first metal layers 120 and the second metal layers 130 after bonding. Therefore, after the bonding is complete, an intermetal layer 150 is formed between the intermediate metal layer 110 and the high-power element 10, and another intermetal layer 150 is also formed between the intermediate metal layer 110 and the substrate 20. The intermetal layer 150 has a higher melting point in comparison to the first metal layers 120 and the second metal layers 130, and has good mechanical properties. Moreover, since the intermediate metal layer 110 has the barrier layers 114, the solid-liquid diffusion reaction stops after completely consuming the first metal layers 130, and the barrier layers 114 and the base layer 112 of the metal patch 100 do not further participate in the solid-liquid diffusion reaction. The composition of the intermetal layer 150 at this point is an alloy formed by the material selected for the first metal layers 120 and the second metal layers 130. However, in another embodiment, after the bonding is complete, the first metal layers 120 are not completely consumed in the solid-liquid diffusion reaction, and at this point, residual first metal layer 120 exists in the bonded metal patch 100. Specifically, the first metal layer 120 exists between the intermetal layer 150 and the intermediate metal layer 110.

Since the material of the second metal layers 130 adopts an indium-tin alloy, the second metal layers 130 have the characteristic of lower melting point at a specific ratio, and therefore the metal patch 100 can be bonded at a lower temperature. As a result, damage to the high-power element 10 from the bonding temperature can be reduced. Moreover, after bonding of the metal patch 100 with the high-power element 10 and the substrate 20 is complete, the bonding interface (i.e., the intermetal layer 150) between the metal patch 100 and the high-power element 10 has higher temperature tolerance and good mechanical strength, and the bonding interface (i.e., the intermetal layer 150) between the metal patch 100 and the substrate 20 also has higher temperature tolerance and good mechanical strength, such that the bonded high-power element 10 and substrate 20 can tolerate high operation temperature. Therefore, for the bonding of the high-power element 10 and the substrate 20, the metal patch 100 has the characteristics of “low-temperature bonding” and “high-temperature usage”.

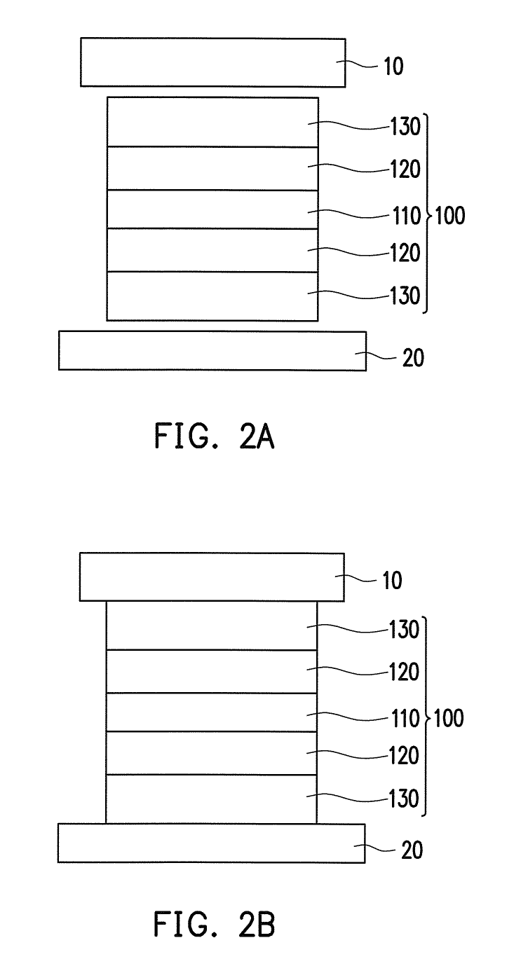

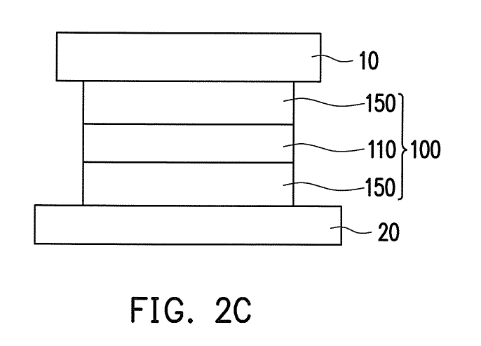

Referring to FIG. 2A, in comparison to the metal patch 100 of the embodiment of FIG. 1A, the intermediate metal layer 110 of the metal patch 100 shown in FIG. 2A is a single-layer structure. In the present embodiment, the intermediate metal layer 110 can be used for blocking and adhering at the same time, and therefore the material selected for the intermediate metal layer 110 needs to have a shielding effect for the solid-liquid diffusion reaction and good bonding for the first metal layers 120. The material of the intermediate metal layer 110 includes nickel or a nickel-phosphorous alloy. Referring to FIG. 2B and FIG. 2C, after the bonding is complete, an intermetal layer 150 is formed between the metal patch 100 and the high-power element 10, and another intermetal layer 150 is also formed between the metal patch 100 and the substrate 20. It should be mentioned that, the above is also exemplified by completely consuming the first metal layers 120 and the second metal layers 130 after bonding. In other embodiments, the first metal layer 120 can also not be completely consumed and exist between the intermetal layer 150 and the intermediate metal layer 110, which is not repeated herein.

In the manufacture, the metal patch 100 can be performed via electroplating and evaporation. In the case of manufacturing the metal patch 100 of FIG. 2A, the intermediate metal layer 110 is used as the substrate, the first metal layers 120 are plated on both sides, and lastly the second metal layers are plated to complete the manufacture. The manufacturing method of the metal patch 100 of FIG. 1A is similar, and can be done by only plating the barrier layers 114 on both sides using the base layer 112 of the intermediate metal layer 110 as the substrate before the first metal layers 120 are plated.

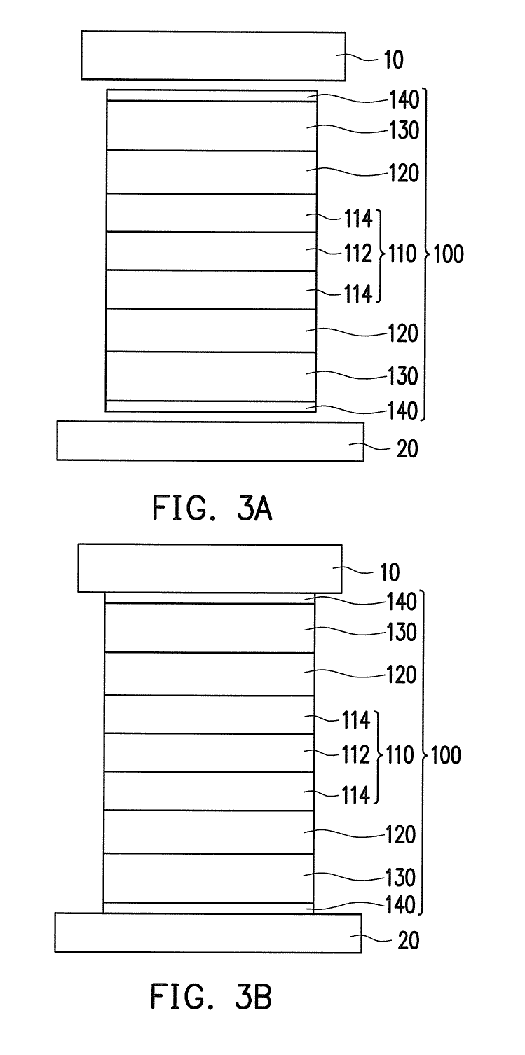

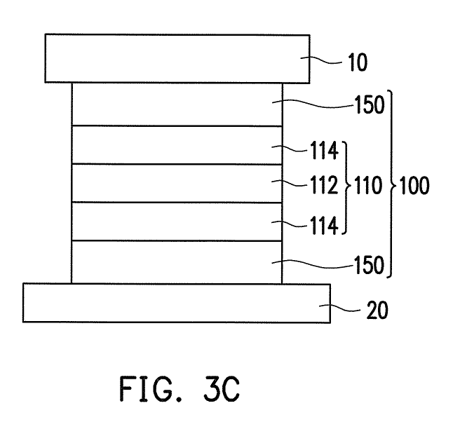

Referring to FIG. 3A, in comparison to the metal patch 100 of the embodiment of FIG. 1A, the metal patch 100 shown in FIG. 3A further includes two wetting layers 140. The wetting layers 140 are respectively disposed on the second metal layers 130, such that the intermediate metal layer 110, the first metal layers 120, and the second metal layers 130 are located between the wetting layers 140. Specifically, the metal patch 100 is a sandwich structure including, in the order of outside to inside, the wetting layers 140, the second metal layers 130, the first metal layers 120, and the intermediate metal layer 110. In the present embodiment, the material of each of the wetting layers 140 includes inorganic chloride, such as zinc chloride. A small amount of the zinc chloride solution having a concentration of, for instance, 0.1% to 1% can be coated on the surface of each of the second metal layers 130 using drop coating or thermal evaporation, and then the moisture of the zinc chloride solution is heated and evaporated or co-evaporated with the second metal layers 130. As a result, a very thin zinc chloride layer (i.e., the wetting layer 140) is formed on the surface of each of the second metal layers 130. Moreover, referring to FIG. 3B and FIG. 3C, after the bonding is complete, an intermetal layer 150 is formed between the metal patch 100 and the high-power element 10, and another intermetal layer 150 is also formed between the metal patch 100 and the substrate 20. It should mentioned that, in the bonding process, the wetting layers 140 can increase the wettability of the second metal layers 130 of the metal patch 100 respectively with the high-power element 10 and the substrate 20, so as to increase the bonding strength between the metal patch 100 and the high-power element 10 and the bonding strength between the metal patch 100 and the substrate 20. Moreover, in the material selected for the wetting layers 140, a portion of metal ions thereof may also participate in the solid-liquid diffusion reaction in the bonding process, such that the intermetal layer 150 formed in the bonding process contains an alloy formed by the metal ions of the wetting layers 140. In the case that zinc chloride is selected for the wetting layers 140 in the present embodiment, the composition of the bonded intermetal layer 150 is an alloy containing zinc and formed by the material selected for the first metal layers 120 and the second metal layers 130.

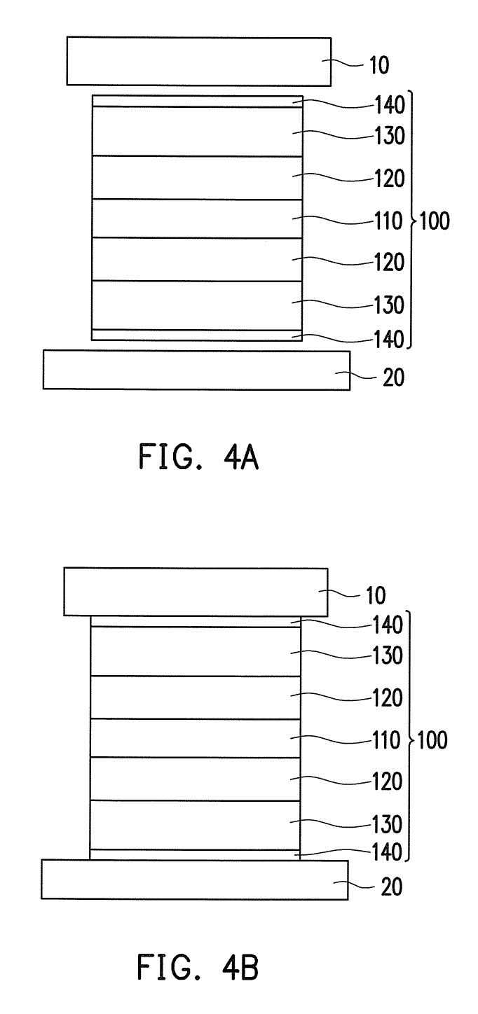

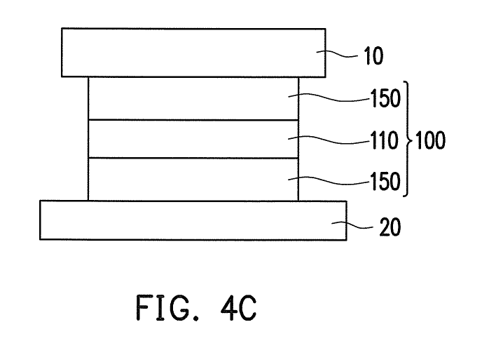

Referring to FIG. 4A, in comparison to the metal patch 100 of the embodiment of FIG. 3A, the intermediate metal layer 110 of the metal patch 100 shown in FIG. 4A is a single-layer structure. In the present embodiment, the material of the intermediate metal layer 110 includes nickel or a nickel-phosphorous alloy. Moreover, referring to FIG. 4B and FIG. 4C, after the bonding is complete, an intermetal layer 150 is formed between the metal patch 100 and the high-power element 10, and another intermetal layer 150 is also formed between the metal patch 100 and the substrate 20. Similarly, in the present embodiment, the wettability of the metal patch 100 with the high-power element 10 and the substrate 20 is also increased by adopting the wetting layers 140 so as to increase bonding strength.

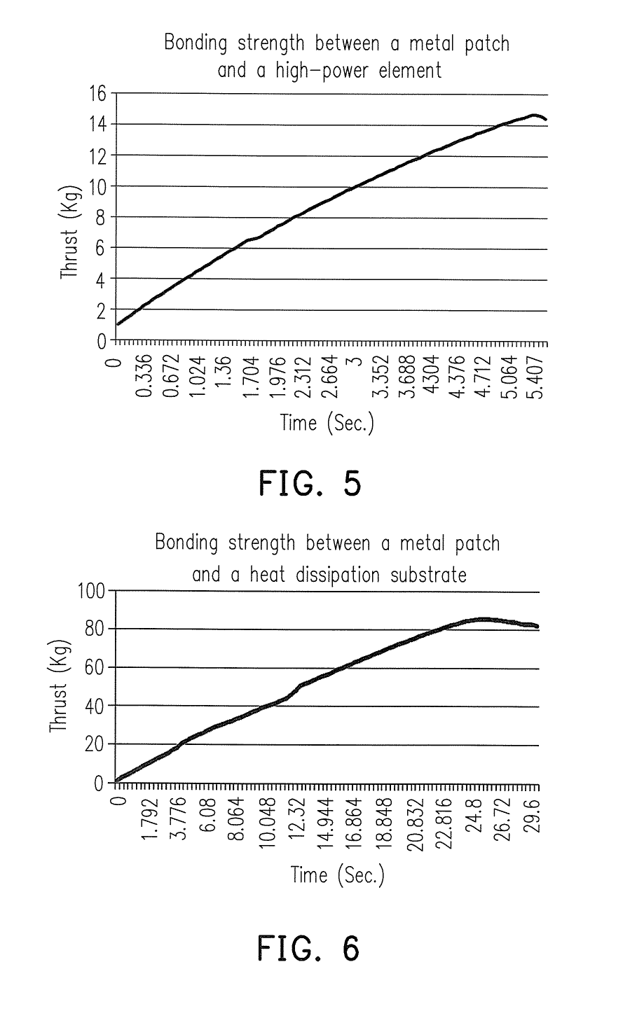

Referring further to FIG. 3A, a method of drop coating is adopted to coat a 1% zinc chloride solution on the surface of the second metal layers 130 (such as indium-tin alloy layers having a composition ratio of 52:48), and then the moisture of the zinc chloride solution is heated and evaporated to form a very thin zinc chloride layer (i.e., the wetting layer 140) on the surface of each of the second metal layers 130. Then, referring further to FIG. 3B and FIG. 3C, low-temperature bonding is performed to bond the metal patch 100 to the high-power element 10 and the substrate 20 (such as copper substrate). After bonding is complete under such conditions, according to US military thrust value MIL-STD-883 TEST METHOD 2019 DIE SHEAR STRENGTH specifications, the relationship of bonding strength between the metal patch 100 and the high-power element 10 against time and thrust can be obtained as shown in FIG. 5, and the relationship of bonding strength between the metal patch 100 and the substrate 20 against time and thrust can be obtained, as shown in FIG. 6. In FIG. 5, the maximum thrust value of the bonding strength between the metal patch 100 and the high-power element 10 reaches 15 kg. In FIG. 6, the maximum thrust value of the bonding strength between the metal patch 100 and the substrate 20 reaches 85 kg. In other words, the bonding of using the metal patch 100 in the present embodiment to bond the high-power element 10 and the substrate 20 is good in both cases.

Based on the above, in the invention, the metal patch can be made beforehand and then connected to the high-power element and the substrate, and therefore a bonding layer (such as a solder layer or a metal layer) does not need to be formed on the high-power element and the substrate beforehand. Moreover, the material of the second metal layers of the metal patch adopts an indium-tin alloy, and therefore the metal patch can be bonded at a lower temperature. After the bonding is complete, the bonding interface (i.e., intermetal layer) between the metal patch and the high-power element has higher temperature tolerance, and the bonding interface (i.e., intermetal layer) between the metal patch and the substrate also has higher temperature tolerance. Therefore, for the bonding of the high-power element and the substrate, the metal patch has the characteristics of “low-temperature bonding” and “high-temperature usage”. Moreover, the metal patch can also include two wetting layers respectively disposed on the second metal layers, and therefore in the bonding process, the wetting layers can increase the wettability of the second metal layers of the metal patch respectively with the high-power element and the substrate, so as to increase the bonding strength between the metal patch and the high-power element and the bonding strength between the metal patch and the substrate.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A metal patch, comprising:
an intermediate metal layer;
two first metal layers respectively disposed on two opposite surfaces of the intermediate metal layer, wherein the intermediate metal layer is located between the first metal layers, and a melting point of each of the first metal layers is greater than 800° C.; and
two second metal layers respectively disposed on the first metal layers, wherein the intermediate metal layer and the first metal layers are located between the second metal layers, a material of each of the second metal layers comprises an indium-tin alloy, and each of the first metal layers and the corresponding second metal layer are capable of generating an intermetal via a solid-liquid diffusion reaction.

2. The metal patch of claim 1, wherein the intermediate metal layer comprises:
a base layer; and
two barrier layers respectively disposed on two opposite surfaces of the base layer, wherein the base layer is located between the barrier layers.

3. The metal patch of claim 2, wherein a material of the base layer comprises copper.

4. The metal patch of claim 2, wherein a thickness of the base layer is 10 micrometers to 50 micrometers.

5. The metal patch of claim 2, wherein a material of each of the barrier layers comprises nickel, a nickel-phosphorus alloy, titanium, or chromium.

6. The metal patch of claim 1, wherein a material of the intermediate metal layer comprises nickel or a nickel-phosphorous alloy.

7. The metal patch of claim 1, wherein a material of each of the first metal layers comprises silver or gold.

8. The metal patch of claim 1, wherein each of the second metal layers contains 5% to 55% of tin.

9. The metal patch of claim 1, wherein an indium-tin percentage of each of the second metal layers is 52:48.

10. The metal patch of claim 1, wherein a melting point range of each of the second metal layers is 118° to 150° C.

11. The metal patch of claim 1, wherein the first metal layer and the corresponding second metal layer are capable of generating an intermetal having a melting point greater than 400° C. via solid-liquid diffusion.

12. The metal patch of claim 1, further comprising:
two wetting layers respectively disposed on the second metal layers, wherein the intermediate metal layer, the first metal layers, and the second metal layers are located between the wetting layers.

13. The metal patch of claim 12, wherein a material of each of the wetting layers comprises inorganic chloride.

14. The metal patch of claim 12, wherein a material of each of the wetting layers comprises zinc chloride.

15. A manufacturing method of a metal patch for manufacturing the metal patch of claim 1, wherein the manufacturing method of the metal patch contains the following steps: plating the first metal layer on both sides by using the intermediate metal layer as a substrate, and then plating the second metal layer.

16. The method of claim 15, wherein before the first metal layer is plated, a barrier layer is plated on both sides by using a base layer of the intermediate metal layer as the substrate.

17. The method of claim 15, further comprising coating a zinc chloride solution on a surface of the second metal layers, and then heating and evaporating a moisture of the zinc chloride solution.

18. The method of claim 17, wherein a concentration range of the zinc chloride solution is 0.1% to 1%.

19. A bonding method using a metal patch, suitable for connecting a high-power element and a substrate, wherein the metal patch adopts the metal patch of claim 1, and the bonding method comprises:
positioning the metal patch between the high-power element and the substrate, such that the metal patch is in contact with the high-power element and the substrate;
performing a preliminary bonding on a contact surface of the metal patch respectively with the high-power element and the substrate at a preliminary bonding temperature higher than a melting point of each of the second metal layers to generate an intermetal thin film at each of the contact surfaces;
performing a solid-liquid diffusion reaction on the preliminarily bonded metal patch, high-power element, and substrate at a bonding temperature higher than a melting point of each of the second metal layers to react a material of each of the first metal layers and the corresponding second metal layer in contact therewith into an intermetal via solid-liquid diffusion until each of the second metal layers is completely consumed.

20. The method of claim 19, wherein the preliminary bonding temperature is 150° C. or 180° C.

21. The method of claim 19, wherein a reaction time of the preliminary bonding is less than 10 seconds.

22. The method of claim 19, wherein the bonding temperature is 150° C. or 180° C.

23. The method of claim 19, wherein a reaction time of the solid-liquid diffusion reaction is greater than or equal to 0.5 hours.
